(19) United States
(12) Patent Application Publication
(10) Pub. No.: US 2026/0333651 A1
(43) Pub. Date: Oct. 22, 2026

(54) FEEDER MANAGEMENT DEVICE AND SET-UP DEVICE

(71) Applicant: FUJI CORPORATION, Chiryu (JP)

(72) Inventor: Mitsuru SANJI, Toyota-shi (JP)

(73) Assignee: FUJI CORPORATION, Chiryu (JP)

(21) Appl. No.: 19/111,448

(22) PCT Filed: Sep. 29, 2022
(86) PCT No.: PCT/JP2022/036559

§ 371 Date: Mar. 13, 2025

(51) Int. Cl. H05K 13/04; H05K 13/08

(52) U.S. Cl. CPC H05K 13/043; H05K 13/086

(57) ABSTRACT

A feeder management device includes a determination section configured to determine whether to permit discharge of a predetermined type of component from a component case set in a bulk feeder and accommodating the component to the bulk feeder based on feeder information relating to the bulk feeder and case information relating to the component case, and a handling process section configured to execute a predetermined handling process based on a determination result of permission for discharge by the determination section.

### TECHNICAL FIELD

The present disclosure relates to a feeder management device and a set-up device.

### BACKGROUND ART

A feeder management device manages a feeder, which supplies components in a component mounter, as a target. As disclosed in Patent Literature 1, there is a type of feeder described above in which components are supplied in a bulk state in which the components are scattered in a supply region where the components are collectable by a suction nozzle. A component case accommodating a large number of components is set in the bulk feeder.

### CITATION LIST

### Patent Literature

Patent Literature 1: WO 2022/162916

### BRIEF SUMMARY

### Technical Problem

In the above-described setup of the bulk feeder, a component case accommodating a component of a different type than planned may be erroneously set. In this case, the component discharged from the component case enters the inside of the feeder, which requires maintenance such as a removal work of the component. The component removed from the bulk feeder is a target to be discarded.

An object of the present description is to provide a feeder management device and a set-up device that prevent a component of a different type than planned from being discharged from a component case in a bulk feeder.

### Solution to Problem

The present description discloses a feeder management device including: a determination section configured to determine whether to permit discharge of a predetermined type of component from a component case set in a bulk feeder and accommodating the component to the bulk feeder based on feeder information relating to the bulk feeder and case information relating to the component case; and a handling process section configured to execute a predetermined handling process based on a determination result of permission for discharge by the determination section.

The bulk feeder includes a case support member detachably attached to a feeder main body and to support the set component case and a conveyance unit including a track member formed with a conveyance path through which the component is conveyed and a supply region for supplying the component in a collectable manner. The present description discloses a set-up device including: a support table configured to support the conveyance unit detached from the feeder main body; and the feeder management device.

### Advantageous Effects

According to such a configuration of the feeder management device, whether to permit discharge is determined based on the feeder information and the case information, and the handling process is carried out based on the determination result, and thus, even when, for example, a component case accommodating the component of the different type than planned is set in the feeder, the handling process can prevent the component from being discharged. As a result, it is possible to prevent the occurrence of maintenance due to an erroneous work, prevent a reduction in production efficiency, and prevent an unnecessary disposal of the component.

### BRIEF DESCRIPTION OF DRAWINGS

FIG. 1 is a schematic diagram illustrating a production system to which a feeder management device and a set-up device are applied.

FIG. 2 is a side view schematically illustrating a part of a bulk feeder including a supply region.

FIG. 3 is a plan view as viewed from a III direction in FIG. 2.

FIG. 4 is a perspective view illustrating an appearance of a conveyance unit constituting the bulk feeder and a set-up device.

FIG. 5 is a block diagram illustrating the set-up device.

FIG. 6 is a diagram illustrating feeder information and case information.

FIG. 7 is a flowchart illustrating feeder management process.

FIG. 8 is a diagram illustrating a shutter opening/closing device in the set-up device.

### DESCRIPTION OF EMBODIMENTS

### 1. Overview of Feeder Management Device 60 and Set-Up Device 50

Feeder management device 60 manages a feeder that supplies a component to component mounter 2, as a target. In the present embodiment, feeder management device 60 is incorporated in set-up device 50 used for setup of a feeder, and bulk feeder 10, which is a kind of feeder, is set as a management target.

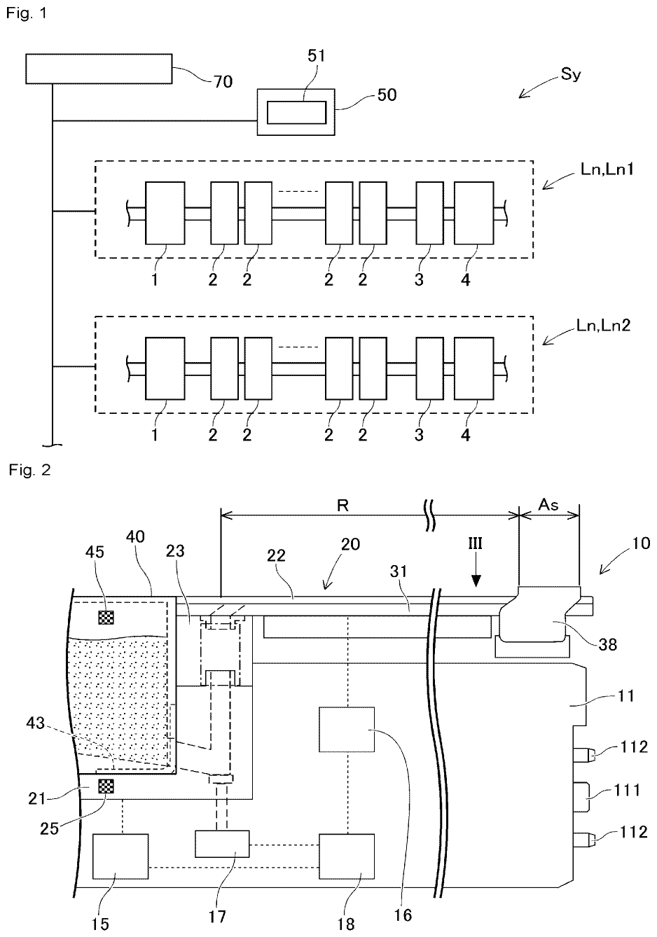

Component mounter 2 executes a mounting process of mounting a component on a board with a predetermined board work. As illustrated in FIG. 1, production line Ln is formed by arranging multiple board work machines in the conveyance direction of the board. Each of the multiple board work machines is communicably connected with host computer 70, which collectively controls production line Ln. Production line Ln includes printer 1, multiple component mounters 2, reflow oven 3, and inspector 4 as multiple board work machines.

Printer 1 prints paste-like solder at a mounting position of the component on board that has been conveyed in. Each of multiple component mounters 2 mounts a component on board conveyed from an upstream side of production line Ln. The configuration of component mounter 2 will be described later. Reflow oven 3 heats board conveyed from the upstream side of production line Ln, melts the solder on board, and performs soldering. Inspector 4 inspects whether an appearance or a function of the board product produced by production line Ln is normal.

In the present embodiment, a factory for producing the board product may be configured with multiple production lines Ln (Ln1, Ln2, . . . ). The configuration of each of multiple production lines Ln can be appropriately equipped with additional configurations or can be appropriately modified in accordance with, for example, the type of board product to be produced. Specifically, a board work machine such as a buffer device for temporarily holding board conveyed, a board supply device, a board flipping device, various types of inspection devices, a shield mounting device, an adhesive application device, an ultraviolet ray irradiation device, or the like can be appropriately installed in multiple production lines Ln.

Set-up device 50 is used for a work of loading a component into a feeder used for a mounting process to be executed, a work of detaching a component from a feeder used for the mounting process, and the like. Set-up device 50 includes a support table 51 that supports the feeder or a part of units detached from the feeder. Set-up device 50 is communicably connected to host computer 70, and inputs and outputs various information relating to setup. A detailed configuration of set-up device 50 will be described later.

### 2. Configuration of Bulk Feeder 10

Bulk feeder 10 targeted by set-up device 50 and feeder management device 60 will be described. Bulk feeder 10 is installed in component mounter 2 and functions as a part of component supply device. Bulk feeder 10 supplies components accommodated in a bulk state in which components are not aligned unlike carrier tapes (in an irregular state in which respective postures thereof are not regular). Therefore, since bulk feeder 10 does not use the carrier tape unlike the tape feeder, there is an advantage in that loading of the carrier tape, collection of the used tape, or the like can be omitted.

For example, there is bulk feeder 10 of a type that supplies components in irregular postures to planar supply region As. However, when the components are so close to one another to contact, the components are accumulated (a state of being overlapped in an up-down direction), or the components are in a horizontally standing posture in which a width direction of the component is directed in the up-down direction in supply region As, component mounter 2 cannot regard these components as a collection target. Then, in order to increase the ratio of components that can be collected, there is bulk feeder 10 of a type that supplies components in an aligned state to supply region As. In the present embodiment, bulk feeder 10 of the type which aligns the components will be described as an example.

### 2-1. Feeder Main Body 11

As illustrated in FIG. 2, bulk feeder 10 includes feeder main body 11. Feeder main body 11 is formed into a flat box shape. Connector 111 and two pins 112 are provided on a front portion (the right side end portion in FIG. 2) of feeder main body 11. When feeder main body 11 is set in a slot of the component supply device, power is supplied via connector 111 and feeder main body 11 becomes communicable with a control device of a component mounter. Two pins 112 are inserted into guide holes provided in slot to thereby be used to position feeder main body 11 when feeder main body 11 is set in slot.

### 2-2. Conveyance Unit 20

As illustrated in FIG. 2, bulk feeder 10 includes conveyance unit 20. Conveyance unit 20 is detachably attached to feeder main body 11. Conveyance unit 20 supports set component case 40 to be described later. Conveyance unit 20 is a unit for conveying from a region for receiving the component discharged from component case 40 to supply region As.

After bulk feeder 10 is used for a predetermined mounting process, removal work to remove all components inside the feeder in preparation for next use is performed as a type of maintenance. Conveyance unit 20 is configured to be detachable from feeder main body 11 as a unit that functions as a flow path of a component in order to improve efficiency, assuming the above-described removal work. In the present embodiment, conveyance unit 20 includes case support member 21, track unit 22, and coupling member 23.

Case support member 21 is provided to be capable of vibrating with respect to feeder main body 11. Case support member 21 is vibrated by first vibration device 15 described later. Case support member 21 supports set component case 40. Case support member 21 receives the component discharged from component case 40. In the present embodiment, the portion of case support member 21 that receives the component has an inclined surface inclined to the front side with respect to a horizontal surface. Case support member 21 is formed with a flow path of a component extending upward from a lower end portion of the inclined surface.

Track unit 22 is provided to be able to vibrate with respect to feeder main body 11. Track unit 22 is vibrated by second vibration device 16 described later. Track unit 22 is formed with conveyance path R through which multiple components are conveyed, and supply region As that communicates with conveyance path R and is open upward such that the multiple components are collectable. Here, “supply region As” is a region in which components are supplied in a bulk state, and is a region in which components can be collected by component mounter 2. The “conveyance path R” is a path of a component in which the component flowing from case support member 21 side to track unit 22 is conveyed to supply region As.

Track unit 22 is formed so as to extend in the front-rear direction (left-right direction in FIG. 2) of feeder main body 11 as an overall shape. In the present embodiment, track unit 22 is attached to track main body 31 such that alignment member 32 can be replaced. Alignment member 32 is, for example, one or multiple plate-shaped members. Track unit 22 is a track member that is unitized by attaching one alignment member 32 selected from multiple types of alignment members 32 corresponding to the shape of multiple types of components to common track main body 31.

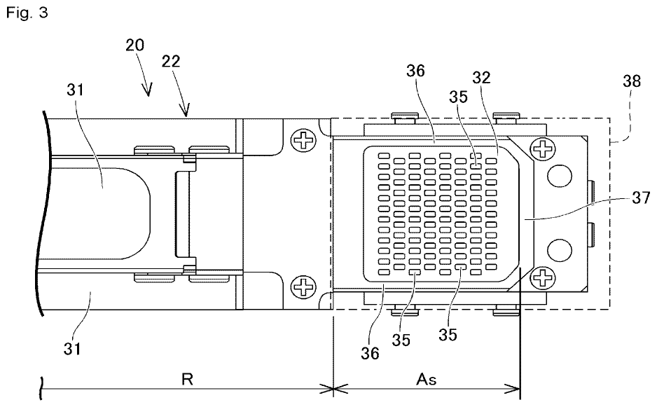

As illustrated in FIG. 3, alignment member 32 constitutes multiple cavities 35 arranged in a predetermined pattern (in a zigzag pattern in the present embodiment). Each of multiple cavities 35 has a rectangular shape slightly larger than the outer shape of the component supplied by bulk feeder 10. As described above, bulk feeder 10 includes multiple cavities 35 in which the components are accommodated in a posture in which the thickness direction of the component is the up-down direction in supply region As to which the components are supplied such that the components can be collected. Pair of side walls 36, which protrudes upwards, is formed along both edges in a width direction (up-down direction in FIG. 3) of track unit 22. Pair of side walls 36 surround the peripheral edge of conveyance path R together with distal end portion 37 of track unit 22 to prevent leakage of the components conveyed on conveyance path R.

Feeder shutter 38 capable of closing the opening of supply region As is provided above track unit 22. When track unit 22 is attached to feeder main body 11, the opening and closing of feeder shutter 38 are controlled by a shutter drive device (not illustrated). By opening and closing feeder shutter 38, bulk feeder 10 can prevent component from protruding and foreign matters from entering supply region As.

Coupling member 23 couples case support member 21 and track unit 22 such that multiple components can flow therebetween. Coupling member 23 has a tubular shape in which the multiple components can flow inside. Coupling member 23 has flexibility and absorbs each vibration by being deformed according to the vibration of case support member 21 and the vibration of track unit 22. Accordingly, coupling member 23 reduces or blocks vibration transmitted between case support member 21 and track unit 22 that vibrate independently from each other.

When attached to feeder main body 11, conveyance unit 20 is supplied with the positive pressure air by air supply device 17, and causes the multiple components to flow from case support member 21 to track unit 22 via coupling member 23. In the present embodiment, air supply device 17 supplies or blocks the positive pressure air supplied from the outside from the lower side of case support member 21 based on a command from feeder control device 18 described later.

### 2-3. First Vibration Device 15 and Second Vibration Device 16

Bulk feeder 10 includes first vibration device 15 and second vibration device 16 provided in feeder main body 11. First vibration device 15 applies vibration to case support member 21 to promote the discharge of the components from set component case 40. Second vibration device 16 applies vibration to track unit 22 so that the multiple components are conveyed along conveyance path R. When second vibration device 16 applies vibration to track unit 22, track unit 22 performs an elliptical motion in a lateral view.

As a result, a forward and upward external force or a rearward and upward external force is applied to multiple components at conveyance path R in accordance with a rotational direction of the elliptical motion of track unit 22. As a result, the multiple components are conveyed to the front side or the rear side of track unit 22. Bulk feeder 10 can vary the conveyance speed of components to be conveyed, the degree of dispersion of components, the conveyance direction, and the like by controlling the frequency and amplitude of the vibration applied to track unit 22, and the rotational direction of the elliptical motion caused by the vibration.

### 2-4. Feeder Control Device 18

Bulk feeder 10 includes feeder control device 18. Feeder control device 18 mainly includes CPU, various memories, or a control circuit. Feeder control device 18 is powered via connector 111 in a state in which bulk feeder 10 is set in the slot of component mounter 2, and can communicate with the control device of component mounter 2.

Various data including a program, a conveyance parameter, and the like for use in controlling a component supply process are stored in feeder control device 18. The above-mentioned “conveyance parameter” is a parameter for controlling the operation of second vibration device 16 so that the vibration applied to track unit 22 is appropriate when the component is conveyed in the component supply process, and is set in advance in association with each type of component, for example.

Feeder control device 18 controls operations of first vibration device 15, second vibration device 16, air supply device 17, the shutter drive device, and the like. For example, feeder control device 18 controls the operation of second vibration device 16 based on a parameter set in advance to execute the component supply process. Accordingly, vibration is applied to track unit 22, and the component on conveyance path R is conveyed by receiving an external force so as to move in the conveyance direction.

### 3. Component Case 40

Component case 40 accommodates the multiple components in a bulk state. Component case 40 is an external device that is replaceably set on case support member 21 in conveyance unit 20 of bulk feeder 10. Component case 40 has case main body 41 formed in a flat box shape similarly to feeder main body 11. Component case 40 includes discharge port 42 through which the accommodated component is discharged to the outside at a front lower portion (a lower right portion in FIG. 2) of case main body 41.

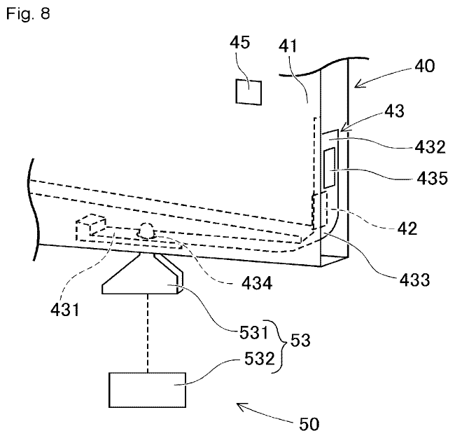

Component case 40 includes shutter 43 that opens and closes the opening of discharge port 42. As illustrated in FIG. 8, shutter 43 includes operation plate 431 extending along the bottom surface portion of case main body 41, shutter plate 432 extending along the front surface portion of case main body 41, and bent portion 433 coupling operation plate 431 and shutter plate 432. Operation hole 434 penetrating in the up-down direction is formed in operation plate 431. Opening 435 communicating with discharge port 42 is formed in shutter plate 432 when shutter plate 432 is positioned at a predetermined position with respect to case main body 41. Bent portion 433 is formed to be bendable following the curved shape of the corner portion of case main body 41.

According to such a configuration, in component case 40, when operation plate 431 slides in the front-rear direction (the left-right direction in FIG. 2, the upper left and lower right directions in FIG. 8), shutter plate 432 coupled by bent portion 433 slides in the up-down direction (the up-down direction in FIGS. 2 and 8). When shutter plate 432 slides downward and opening 435 communicates with discharge port 42, shutter 43 is in the open state, and the component can be discharged to the outside. Meanwhile, when shutter plate 432 slides upward and opening 435 is displaced with respect to discharge port 42, shutter 43 is in the closed state, and the component is in a state of being unable to be discharged to the outside.

The opening and closing operation of shutter 43 is performed by, for example, the worker inserting a dedicated jig into operation hole 434 and sliding operation plate 431 in a state where component case 40 is set in conveyance unit 20. Further, the opening and closing operation of shutter 43 is automatically performed by shutter opening/closing device 53 of set-up device 50 as illustrated in FIG. 8 in a state in which conveyance unit 20 in which component case 40 is set is supported by set-up device 50 described later. A detailed configuration of set-up device 50 will be described later.

### 4. Component Supply Process of Bulk Feeder 10

A component supply process by bulk feeder 10 configured as described above will be described. First, feeder control device 18 discharges the component from component case 40 based on, for example, a supply command from the outside. Specifically, feeder control device 18 controls the operation of first vibration device 15 such that vibration is applied to case support member 21 to which component case 40 is attached. When component case 40 vibrates, the component is discharged from discharge port 42. The discharged component drops to the inclined portion of case support member 21 positioned below discharge port 42 and slides forward along the inclined surface of the inclined portion. Accordingly, the components stay at the lower end portion in front of the inclined portion.

In this state, feeder control device 18 instructs air supply device 17 to supply the positive pressure air. The positive pressure air supplied from air supply device 17 blows up the multiple staying components, and flows through the flow path formed in case support member 21 together with the component. As a result, the positive pressure air and the multiple components flow from case support member 21 to track unit 22 via coupling member 23, and reach conveyance path R of track unit 22. Here, the positive pressure air is exhausted to the outside from an exhaust port formed in the cover of track unit 22.

Thereafter, when second vibration device 16 for conveying the component applies vibration to track unit 22, multiple components are conveyed to supply region As side. In addition, vibration for moving component forward or rearward is applied to track unit 22 in accordance with the supply amount of the component in supply region As, or the like. Some of the multiple components conveyed to supply region As are accommodated in cavity 35. The components that are not accommodated in cavity 35 are further retreated to conveyance path R by the vibration applied by second vibration device 16, and are removed from supply region As. According to the component supply process, the components accommodated in multiple cavities 35 are supplied in a state in which the components can be collected by component mounter 2.

### 5. Set-up Device 50

### 5-1. Overview of Set-Up Device 50

Set-up device 50 is installed, for example, in an off-line set-up area between a warehouse for storing components (not illustrated) or the like and production line Ln in a production facility of a product board. In the off-line set-up area, a work of loading components such that various types of feeders can supply components can be automatically performed by set-up device 50, or can be manually performed by a worker. Set-up device 50 also supports a part of the work of loading components. Between the off-line set-up area and the warehouse, and between the off-line set-up area and production line Ln, an automated guided vehicle or the worker can convey a feeder or a component.

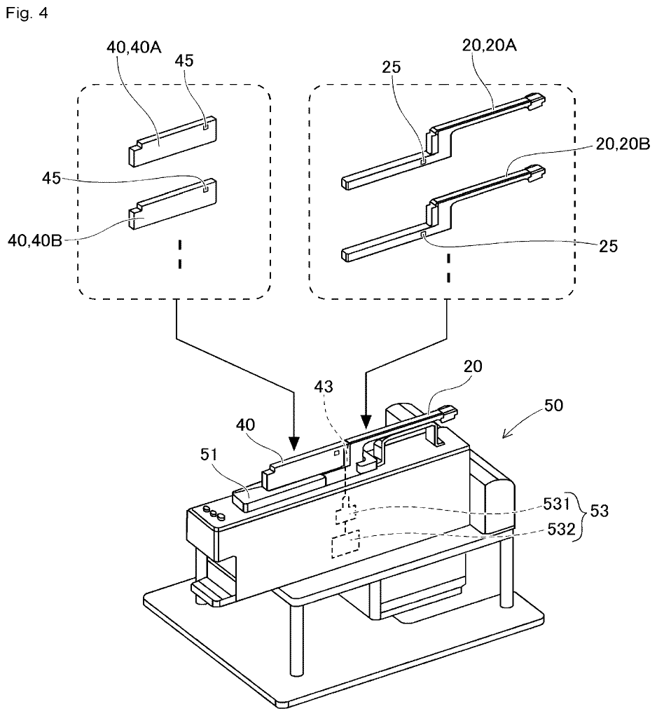

In the present embodiment, as illustrated in FIG. 4, set-up device 50 sets component case 40 in conveyance unit 20 detached from bulk feeder 10, switches shutter 43 to the open state, and supports the work of achieving a state in which conveyance unit 20 causes the component to flow. Further, set-up device 50 associates component case 40 set in conveyance unit 20 and performs a work of registering the combination in host computer 70.

Here, conveyance unit 20 differs in the types of components compatible with the supply (hereinafter, referred to as a “compatible component type”) depending on the type of alignment member 32 of track unit 22, specifically, the shape of cavity 35. This is because, depending on the shape of the component and the shape of cavity 35, the component is not accommodated in cavity 35 or is not aligned appropriately even if accommodated in cavity 35. That is, conveyance unit 20 is classified according to the compatible component type as an example (20A, 20B, . . . in FIG. 4), and is selected according to the type of component to be supplied.

Component case 40 is classified according to the type (hereinafter referred to as “accommodation component type”) of component to be accommodated. That is, component case 40 is classified according to the accommodation component type (40A, 40B, . . . in FIG. 4), and is selected according to the type of component to be supplied. Conveyance unit 20 and component case 40 may be classified according to the functions and characteristics of conveyance unit 20 and component case 40 in addition to or instead of a new type of a compatible portion and the accommodation component type.

In the present embodiment, identification codes indicating respective identification information are attached to bulk feeder 10 and component case 40. Since the present embodiment adopts the configuration in which conveyance unit 20 is replaceable with respect to feeder main body 11, unit code 25 is attached to conveyance unit 20 as an identification code. Case code 45 is attached to component case 40 as an identification code. Unit code 25 and case code 45 may be barcodes or 2D codes, or may be codes to which RFID is applied.

### 5-2. Configuration of Set-Up Device 50

As illustrated in FIG. 4, set-up device 50 includes support table 51. Support table 51 supports conveyance unit 20 detached from feeder main body 11 of bulk feeder 10. Support table 51 has a support structure similar to that of feeder main body 11, and supports case support member 21 and track unit 22 of conveyance unit 20.

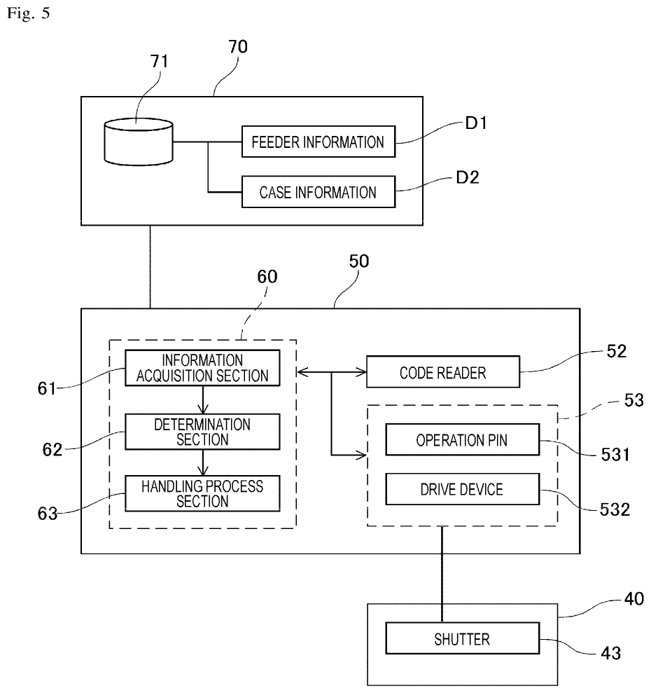

As illustrated in FIG. 5, set-up device 50 includes code reader 52. Code reader 52 reads unit code 25 of conveyance unit 20 and case code 45 of component case 40, and acquires the identification information. Code reader 52 may be, for example, a hand scanner, or may be configured to perform reading when conveyance unit 20 or component case 40 is positioned at a predetermined position with respect to support table 51.

As illustrated in FIGS. 4 and 5, set-up device 50 includes shutter opening/closing device 53. Shutter opening/closing device 53 includes operation pin 531 and drive device 532. As illustrated in FIG. 8, operation pin 531 is disposed below shutter 43 of component case 40 set in conveyance unit 20. Operation pin 531 is configured to be lifted and lowered in the up-down direction and slidable in the front-rear direction. Drive device 532 lifts and lowers operation pin 531 between a height at which operation pin 531 is inserted and a height at which operation pin 531 is separated from operation hole 434 of shutter 43. Drive device 532 slides operation pin 531 in the front-rear direction in a state where operation pin 531 is inserted into operation hole 434.

As described above, when drive device 532 of shutter opening/closing device 53 drives operation pin 531, operation plate 431 of shutter 43 moves in the front-rear direction, and thus, shutter plate 432 moves in the up-down direction. As a result, the open state and the closed state of shutter 43 are switched by shutter opening/closing device 53.

### 6. Feeder Management Device 60

### 6-1. Overview of Feeder Management Device 60

Here, in the setup of bulk feeder 10, component case 40 that accommodates a component of a different type than planned may be erroneously set in conveyance unit 20. Thus, when the component discharged from component case 40 enters bulk feeder 10, maintenance such as the removal work of components is required. Further, the component removed from the bulk feeder can affect the production cost of the product board which is a target to be discarded.

In the present embodiment, feeder management device 60 incorporated in set-up device 50 is configured to prevent a component of a different type than planned from being discharged from component case 40 in bulk feeder 10. Specifically, feeder management device 60 includes determination section 62 and handling process section 63, as illustrated in FIG. 5. In the present embodiment, feeder management device 60 further includes information acquisition section 61.

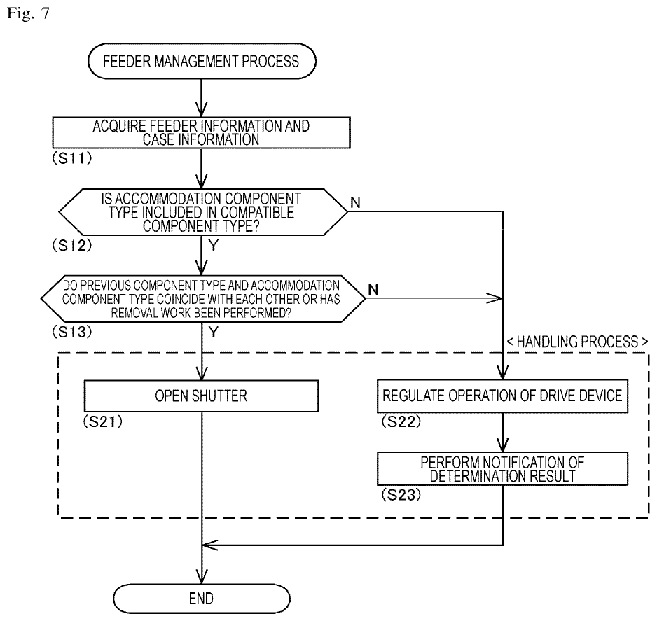

Feeder management device 60 executes feeder management process illustrated in FIG. 7. Hereinafter, each step of feeder management process and detailed description of each configuration of feeder management device 60 will be described in association with each other. The feeder management process is executed when, for example, predetermined conveyance unit 20 is set in set-up device 50, predetermined component case 40 is supported by conveyance unit 20, and the identification codes of conveyance unit 20 and component case 40 are read.

### 6-2. Information Acquisition Section 61

Information acquisition section 61 acquires the identification information by code reader 52 reading each of the identification codes (unit code 25 and case code 45). Then, information acquisition section 61 acquires feeder information D1 and case information D2 associated with each identification information (S11). In the present embodiment, storage section 71 of host computer 70 stores feeder information D1 associated with each unit code 25 of multiple bulk feeders 10 and case information D2 associated with each case code 45 of multiple component cases 40.

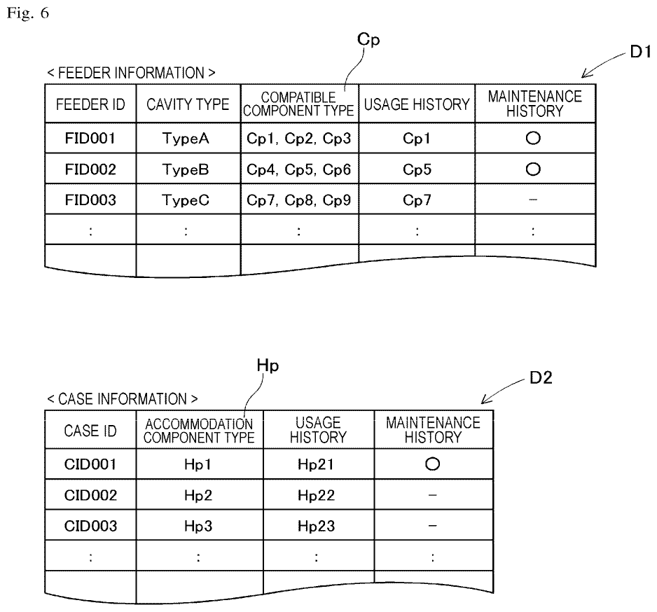

Specifically, feeder information D1 is information relating to bulk feeder 10, and as illustrated in the upper part of FIG. 6, for each identification code (ID) of conveyance unit 20, a cavity type, a compatible component type (Cp1, Cp2, . . . ), a usage history, and a maintenance history are recorded. The cavity type corresponds to the type of alignment member 32 attached to track unit 22. Compatible component type Cp indicates the types of components which can be appropriately supplied by bulk feeder 10 to which conveyance unit 20 is attached according to the cavity type. Compatible component type Cp may indicate component types themselves, or may comprehensively indicate component types by means of the outer shapes and dimensions of the components.

The usage history indicates the type of the component supplied by bulk feeder 10 in the previous use. The maintenance history indicates whether the removal work of the component has been performed after the previous use of bulk feeder 10. Since the usage history and the maintenance history are additional information, the feeder management can be performed even when the information is insufficient. However, when the usage history and the maintenance history are included in feeder information D1, the management performance can be further improved.

Case information D2 is information relating to component case 40 that accommodates a predetermined type of component, and as illustrated in the lower portion of FIG. 6, accommodation component type Hp, the usage history, and the maintenance history are recorded for each identification code (ID) of component case 40. In accommodation component type Hp, when component case 40 is of a type capable of replenishing components, type of the component is associated with the ID of component case 40 when the component is replenished to component case 40. Since the usage history and the maintenance history of component case 40 are the same as the usage history and the maintenance history in feeder information D1, a detailed description thereof is omitted.

In the present embodiment, information acquisition section 61 acquires feeder information D1 and case information D2 associated with the identification code read by code reader 52 from host computer 70. When compatible component type Cp, accommodation component type Hp, and various kinds of history information are recorded in unit code 25 and case code 45 in addition to the ID, the inquiry to host computer 70 may be omitted.

### 6-3. Determination Section 62

determination section 62 determines whether the component is permitted to be discharged from component case 40 to bulk feeder 10 based on feeder information D1 and case information D2. The determination process of permission for discharge is a determination as to whether the component accommodated in component case 40 is permitted to be discharged so as to enter the inside of conveyance unit 20 in the present embodiment.

The determination process is based on feeder information DI and case information D2, and various aspects may be adopted. In the present embodiment, when accommodation component type Hp in case information D2 is not included in compatible component type Cp in feeder information D1 (S12: No), determination section 62 determines that the discharge of the component is not permitted. Further, when accommodation component type Hp in case information D2 is included (S12: Yes), determination section 62 may execute the determination process based on the usage history and the maintenance history. Specifically, when the type of the component indicated by the usage history is different from that of accommodation component type Hp and the removal work has not been performed by the maintenance history (S13: No), determination section 62 does not permit the discharge of the component.

That is, when the type (hereinafter, referred to as a “previous component type”) of the component supplied by bulk feeder 10 in the previous use coincides with accommodation component type Hp (S13: Yes), determination section 62 permits the discharge of the component. When the previous component type and accommodation component type Hp are not coincident with each other and the removal work has been performed by the maintenance history (S13: Yes), determination section 62 permits the discharge of the component. The reason why the discharge of the component is permitted as in the above two examples is that, in the setup for supplying the same type of component, it is possible to prevent the different type of component from being mixed regardless of the presence or absence of the removal work after the previous use.

Meanwhile, when the previous component type and accommodation component type Hp are not coincident with each other and the removal work has not been performed (S13: No), determination section 62 does not permit the discharge of the component. According to such a determination, for example, even if planned component case 40 is set in conveyance unit 20 and accommodation component type Hp is included in compatible component type Cp, it is possible to prevent the mixture with the different type of component that may remain inside conveyance unit 20 due to insufficient maintenance.

In addition to the above determination, determination section 62 may adopt an aspect in which the discharge of the component is not uniformly permitted when the removal work is not performed by the maintenance history, regardless of the usage history. The determination process may be limited to the comparison between compatible component type Cp and accommodation component type Hp, and the determination based on the usage history and maintenance history may be omitted.

### 6-4. Handling Process Section 63

Based on the determination result by determination section 62 as to whether the discharge is permitted, predetermined handling process (S21 to S23) is executed. Specifically, when the discharge of the component is permitted (S13: Yes), handling process section 63 permits the operation of drive device 532 in shutter opening/closing device 53 in the handling process, and opens shutter 43 (S21). Meanwhile, when the discharge of the component is not permitted (S12: No, S13: No), handling process section 63 regulates the operation of drive device 532 that opens and closes shutter 43 of component case 40 supported by case support member 21 in the handling process (S22).

In the handling process, when the determination result indicates that the discharge of the component is not permitted (S12: No, S13: No), handling process section 63 notifies the worker who sets component case 40 to bulk feeder 10, of the determination result to (S23). Thus, the worker can recognize that attached component case 40 does not conform to conveyance unit 20 set in set-up device 50. As a result, it is possible to prevent the component other than planned from being discharged from unsuitable component case 40 to conveyance unit 20.

In a case where set-up device 50 includes shutter opening/closing device 53 as described above, handling process section 63 can take measures by regulating the operation of shutter opening/closing device 53. In addition, handling process section 63 may operate, for example, a lock mechanism (not illustrated) that locks opening and closing of shutter 43 of component case 40 in the handling process. In the above embodiment, the handling process is made by regulating the movement of shutter 43 of component case 40 to the open state. Meanwhile, for example, the handling process may be made by inserting a shield plate, which is separate from shutter 43, between component case 40 and case support member 21, and whether removing the shield plate.

### 7. Effects of Configuration of Embodiment

According to the configuration of feeder management device 60 exemplified in the embodiment, determination of whether to permit discharge is made based on feeder information DI and case information D. Then, by performing the handling process based on the determination result, for example, even when component case 40 accommodating a component of a different type than planned is set in bulk feeder 10, the handling process can prevent the component from being discharged. As a result, it is possible to prevent the occurrence of maintenance due to an erroneous work, prevent a reduction in production efficiency, and prevent an unnecessary disposal of the component. By applying such a feeder management device 60 to set-up device 50, it is particularly useful to improve the setup efficiency.

### 8. Modifications of Embodiment

In the embodiment, feeder management device 60 is incorporated in set-up device 50. Meanwhile, a part or the whole of feeder management device 60 may be an external device different from set-up device 50. For example, a part or the whole of feeder management device 60 may be incorporated in component mounter 2, host computer 70, or bulk feeder 10, or may be a dedicated device installed in an off-line set-up area or the like.

In the embodiment, bulk feeder 10 supplies components to be mounted on the board by component mounter 2. Meanwhile, the component is used in a board work machine which executes a predetermined work on the board as in component mounter 2, and various types of components can be applied as long as the article can be supplied in a state of being accommodated in cavity 35 in the bulk feeder. For example, bulk feeder 10 may supply a solder ball formed in a spherical shape. Even in such an aspect, effects similar to those of the embodiment are obtained.

### REFERENCE SIGNS LIST

2: component mounter, 10: bulk feeder, 11: feeder main body, 20, 20A, 20B: conveyance unit, 21: case support member, 22: track unit (track member), 31: track main body, 32, 32A, 32B: alignment member, 35: cavity, 36: side wall, 37: distal end portion, 38: feeder shutter, 23: coupling member, 25: unit code (identification code), 40, 40A, 40B: component case, 41: case main body, 42: discharge port, 43: shutter, 45: case code (identification code), 50: set-up device, 51: support table, 52: code reader, 53: shutter opening/closing device, 531: operation pin, 532: drive device, 60: feeder management device, 61: information acquisition section, 62: determination section, 63: handling process section, 70: host computer, D1: feeder information, D2: case information, Cp: compatible component type, Hp: accommodation component type, As: supply region, R: conveyance path, Sy: production system, Ln, Ln1, Ln2: production line

1. A feeder management device comprising:
a determination section configured to determine whether to permit discharge of a predetermined type of component from a component case set in a bulk feeder accommodating the component to the bulk feeder based on feeder information relating to the bulk feeder and case information relating to the component case; and
a handling process section configured to execute a predetermined handling process based on a determination result of permission for discharge by the determination section.

2. The feeder management device according to claim 1,
wherein the feeder information includes a compatible component type indicating a type of the component compatible with supply of the bulk feeder,
the case information includes an accommodation component type indicating the type of the component accommodated in the component case, and
the determination section determines that the discharge of the component is not permitted when the accommodation component type is not included in the compatible component type.

3. The feeder management device according to claim 2,
wherein the bulk feeder includes multiple cavities configured to accommodate the component in a supply region to which the component is supplied such that the component can be collected, and
the compatible component type is set in advance according to a shape of the cavity.

4. The feeder management device according to claim 1,
wherein the feeder information includes a usage history indicating the type of the component supplied by the bulk feeder in a previous use and a maintenance history indicating whether a removal work of the component is performed after the previous use,
the case information includes an accommodation component type indicating the type of the component accommodated in the component case, and
the determination section does not permit the discharge of the component when the type of the component indicated by the usage history is different from the accommodation component type and the removal work is not performed based on the maintenance history.

5. The feeder management device according to claim 1,
wherein the bulk feeder includes a case support member configured to support the set component case,
the component case includes a discharge port through which the component to be accommodated is discharged to an outside, and a shutter configured to open and close an opening of the discharge port, and
the handling process section regulates an operation of a drive device configured to open and close the shutter of the component case supported by the case support member in the handling process.

6. The feeder management device according to claim 1, wherein
the component case includes a discharge port through which the component accommodated is discharged to an outside, and a shutter configured to open and close an opening of the discharge port, and
the handling process section operates a lock mechanism configured to lock opening and closing of the shutter of the component case in the handling process.

7. The feeder management device according to claim 1, wherein the handling process section notifies the determination result to a worker who sets the component case to the bulk feeder when the determination result indicates that the discharge of the component is not permitted in the handling process.

8. The feeder management device according to claim 1,
wherein an identification code indicating identification information of each of the bulk feeder and the component case is attached to each of the bulk feeder and the component case, and
the feeder management device further includes an information acquisition section configured to acquire the identification information by reading each identification code and acquire the feeder information and the case information associated with each identification information.

9. A set-up device in which the bulk feeder includes a case support member detachably attached to a feeder main body and to support the set component case and a conveyance unit including a track member formed with a conveyance path through which the component is conveyed and a supply region to which the component is supplied such that the component can be collected, the set-up device comprising:
a support table configured to support the conveyance unit detached from the feeder main body; and
the feeder management device according to claim 1.
